(19) United States
(12) Patent Application Publication
(10) Pub. No.: US 2012/0171048 A1
(43) Pub. Date: Jul. 5, 2012

(54) ELECTRONIC DEVICE WITH MINIATURE HEAT DISSIPATING STRUCTURE

(75) Inventor: PING-YANG CHUANG, Tu-Cheng (TW)

(73) Assignee: HON HAI PRECISION INDUSTRY CO., LTD., New Taipei (TW)

(21) Appl. No.: 13/070,472

(22) Filed: Mar. 23, 2011

(30) Foreign Application Priority Data
Dec. 30, 2010 (TW) 99146925

(51) Int. Cl. F04B 49/10; H05K 7/20

(52) U.S. Cl. 417/32; 361/688; 361/699

(57) ABSTRACT

An electronic device includes a circuit board comprising a first metal layer and a second metal layer. The first metal layer is affixed to one side of the circuit board, and the second metal layer is affixed to the first metal layer. A channel is defined between the first metal layer and the second metal layer. A coolant container is used to accommodate coolant. A driving unit is used to drive the coolant to circuit in the channel.

### BACKGROUND

1. Technical Field

The present disclosure relates to an electronic device having a miniature heat dissipating structure.

2. Description of Related Arts

Many computers, such as desktop computers and laptop computers, include heat dissipating devices, such as heat sinks. One problem with the heat dissipating devices is that they occupy precious space, which makes it difficult to further reduce the size of computers.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic planar view of an electronic device according to one exemplary embodiment.

FIG. 2 is a side view of a circuit board of the electronic device of FIG. 1.

FIG. 3 is a block diagram of the electronic device of FIG. 1.

### DETAILED DESCRIPTION

Embodiments of the present disclosure will now be described in detail below, with reference to the accompanying drawings.

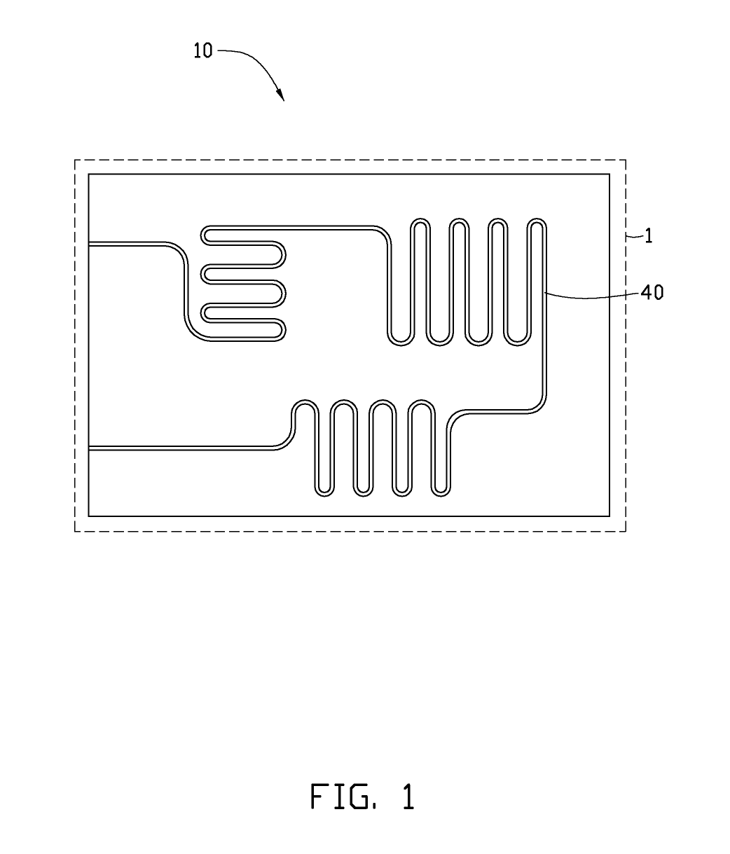

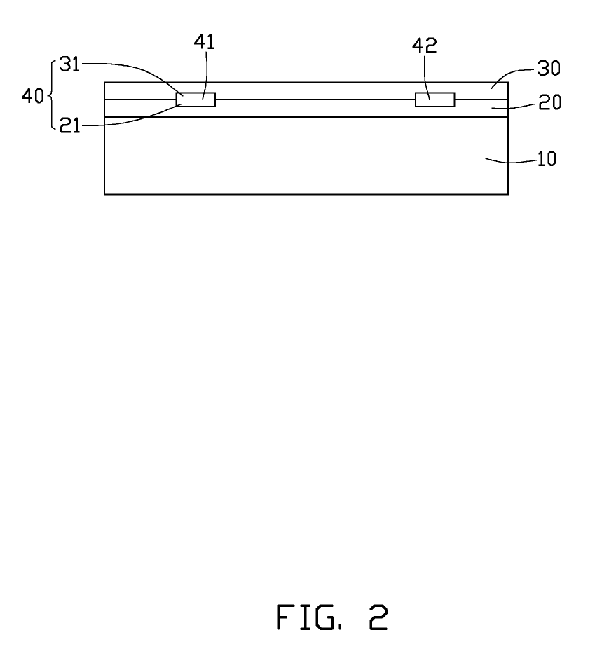

Referring to FIGS. 1 and 2, an electronic device 1 includes a circuit board 10 having a number of electronic components (not shown) on its upper side. The lower side of the circuit board 10 includes a first metal layer 20 and a second metal layer 30. The metal layers 20 and 30 have substantially the same size as the circuit board 10. The first metal layer 20 is affixed to the circuit board 10, and the second metal layer 30 is affixed to the first metal layer 20. In the embodiment, the first metal layer 20 can be made of copper, and the second metal layer 30 can be made of aluminum.

Referring to FIG. 2, the first metal layer 20 defines a groove 21, and the second metal layer 30 defines a groove 31. The grooves 21 and 31 cooperatively form a channel 40 having an inlet 41 and an outlet 42. The edges of the metal layers 20 and 30 are sealed by material, such as glue.

In the embodiment, the channel 40 is configured in a predetermined pattern in areas where a large amount of thermal energy is generated, such as the area where a central processing unit (CPU) is mounted. The predetermined pattern can be a number of parallel sections as shown in FIG. 1, thereby allowing a coolant flowing in the channel 40 to pass through the areas of greatest heat.

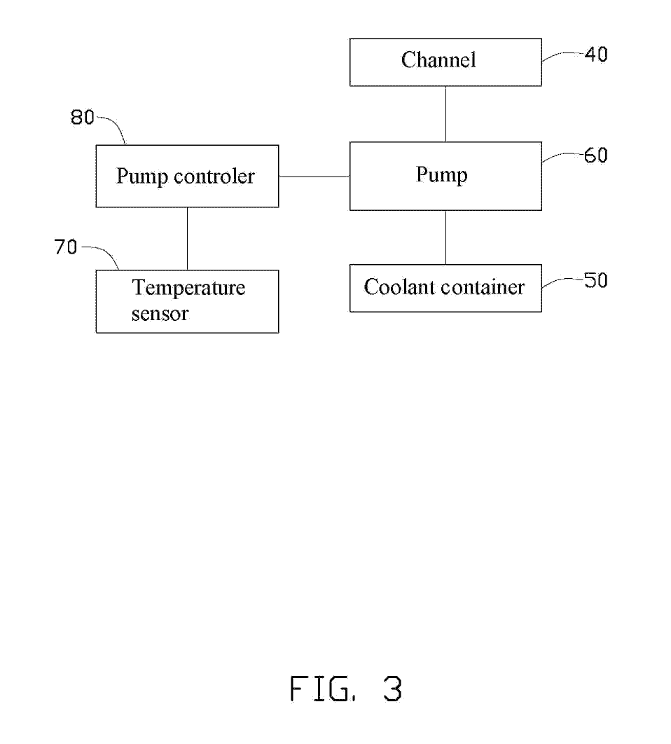

Referring to FIG. 3, in the embodiment, the electronic device 1 further includes a coolant container 50, a micro pump 60, a temperature sensor 70, and a pump controller 80. The container 50 is used to accommodate a coolant, such as water. The micro pump 60 is connected between the container 50 and the channel 40. The pump controller 80 is used to drive the coolant to flow in the channel 40.

The temperature sensor 70 is used to detect the temperature inside the electronic device 1. When the detected temperature exceeds a preset value, the pump controller 80 actuates the pump 60. The coolant then flows in the channel 40 to dissipate heat generated by the circuit board 10.

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. An electronic device comprising:
a circuit board comprising a first metal layer and a second metal layer, the first metal layer being affixed to one side of the circuit board, the second metal layer being affixed to the first metal layer, wherein a channel is defined between the first metal layer and the second metal layer;
a coolant container to accommodate coolant; and
a driving unit to drive the coolant to circuit in the channel.

2. The electronic device according to claim 1, wherein the first metal layer is made of copper and the second metal layer is made of aluminum.

3. The electronic device according to claim 1, wherein the coolant is water.

4. The electronic device according to claim 1, wherein the driving unit is a pump.

5. The electronic device according to claim 1, further comprising a pump controller and a temperature sensor, wherein the temperature sensor is used to detect temperature inside the electronic device, and when the temperature detected by the temperature sensor exceeds a preset value, the pump controller actuates the driving unit to drive the coolant to circuit in the channel.

6. The electronic device according to claim 1, wherein the first metal layer defines a first groove, the second metal layer defines a second groove, the first groove and the second groove cooperatively form the channel.
